(19) United States
(12) Patent Application Publication
(10) Pub. No.: US 2025/0370006 A1
(43) Pub. Date: Dec. 4, 2025

(54) APPARATUS AND METHOD FOR LOCKING PROBE CARD

(71) Applicant: YC Corporation, Seongnam-si (KR)

(72) Inventors: Dong Je JEON, Seongnam-si (KR); Min Su JEON, Seongnam-si (KR); Seok Jae HONG, Seongnam-si (KR); Kwang Hwa LEE, Seongnam-si (KR)

(73) Assignee: YC Corporation, Seongnam-si (KR)

(21) Appl. No.: 19/015,082

(22) Filed: Jan. 9, 2025

(30) Foreign Application Priority Data
May 30, 2024 (KR) 10-2024-0070576
Jul. 4, 2024 (KR) 10-2024-0087987

(51) Int. Cl. G01R 1/073; G01R 31/28

(52) U.S. Cl. CPC G01R 1/07342; G01R 31/2889

(57) ABSTRACT

There is provided an apparatus for locking a probe card. The apparatus may comprise a test head including one or more test boards, a probe card. a base unit disposed between the test head and the probe card and coupled to each of the test head and the probe card, including a plurality of balance adjustment assemblies and a plurality of sensors measuring a plurality of displacement values of a plurality of points of the probe card and a controller determining whether the probe card is in an equilibrium state, based on the plurality of displacement values measured from the plurality of sensors, and controlling the probe card to be in an equilibrium state by adjusting a length of at least one of the plurality of balance adjustment assemblies when it is determined that the probe card is out of the equilibrium state.

### CROSS-REFERENCE TO RELATED APPLICATION

This application claims priority from Korean Patent Application No. 10-2024-0070576 filed on May 30, 2024 and Korean Patent Application No. 10-2024-0087987 filed on Jul. 4, 2024 in the Korean Intellectual Property Office and all the benefits accruing therefrom under 35 U.S.C. 119, the contents of which in its entirety are herein incorporated by reference.

### BACKGROUND

### Technical Field

The present disclosure relates to an apparatus and method for locking a probe card used to test a device under test.

### Description of the Related Art

In order to test a semiconductor device, a probe card may be used. The probe card is in contact with a device under test (DUT) on a wafer. A test signal is transmitted to the device under test through the probe card, and a signal responded from the device under test may be analyzed to determine whether or not the device under test is defective.

However, when the probe card is in contact with the wafer, a significant large load may be added to the probe card.

FIG. 1 is a view illustrating a test system, and FIG. 2 is a view illustrating a state that a probe card 50 is in contact with a wafer 60.

As shown in FIGS. 1 and 2, the test system tests the device under test by using a tester 10, a cable 20, a test head 30, a base unit 40, and a probe card 50.

After a lower surface of the probe card 50 is in contact with an upper surface of the wafer 60, a test signal generated through the tester 10 may be applied to the device to be tested (DUT) on the wafer 60 via a cable 20, a board in the test head 30 and the probe card 50.

However, when the wafer 60 is in contact with the probe card 50, a significant large load may be generated. For example, load of about 200 kg or more may be generated. Also, when the probe card 50 is repeatedly in contact with the wafer 60, a contact state between the probe card 50 and the wafer 60 may become unstable. For example, when the probe card 50 is repeatedly in contact with the wafer 60, the probe card 50 may be inclined due to the load, and thus, alignment between the probe card 50 and the wafer 60 may be misaligned.

When the probe card 50 is inclined (i.e., not in an equilibrium state), load of the wafer 60 may be concentrated on a specific area without being dispersed. In this case, the test for the device under test included in the wafer 60 may be performed in error.

Accordingly, there is a demand for a technology capable of stably contacting the probe card 50 with the wafer 60.

### BRIEF SUMMARY

An object of the present disclosure is to provide an apparatus and method for locking a probe card, which is capable of maintaining an equilibrium state between a probe card and a wafer and stably connecting the probe card to the wafer.

Another object of the present disclosure is to provide an apparatus and method for locking a probe card, which is intended to disperse load applied to a wafer when a probe card is in contact with the wafer.

The objects of the present disclosure are not limited to those mentioned above and additional objects of the present disclosure, which are not mentioned herein, will be clearly understood by those skilled in the art from the following description of the present disclosure.

According to an aspect of the present disclosure, there is provided an apparatus for locking a probe card. The apparatus may comprise a test head including one or more test boards, a probe card. a base unit disposed between the test head and the probe card and coupled to each of the test head and the probe card, including a plurality of balance adjustment assemblies and a plurality of sensors measuring a plurality of displacement values of a plurality of points of the probe card and a controller determining whether the probe card is in an equilibrium state, based on the plurality of displacement values measured from the plurality of sensors, and controlling the probe card to be in an equilibrium state by adjusting a length of at least one of the plurality of balance adjustment assemblies when it is determined that the probe card is out of the equilibrium state.

In some embodiments, the controller may determine a target balance adjustment assembly to be adjusted in length among the plurality of balance adjustment assemblies, based on a deviation or difference of the plurality of displacement values when the probe card is out of the equilibrium state, and may adjust a length of the determined target balance adjustment assembly.

In some embodiments, the controller may determine a shortened length or an extension length of the determined target balance adjustment assembly, based on the deviation or difference of the plurality of displacement values, and may control the length of the determined target balance assembly based on the determined shortened length or the determined extension length.

In some embodiments, the controller may determine a rotation direction and the number of rotations of a motor based on the deviation or difference of the plurality of displacement values, and may control the motor included in the determined target balance adjustment assembly based on the determined rotation direction and the number of rotations to adjust the length of the determined target balance adjustment assembly.

In some embodiments, the base unit further may include a center clamp and an inclined block formed above the center clamp, enabling one end of the plurality of balance adjustment assemblies to ascend or descend.

In some embodiments, each of the plurality of balance adjustment assemblies may include a motor, a length adjustment member coupled to one end of the motor and lengthened in a direction of the inclined block or shortened in an opposite direction of the inclined block in accordance with rotation of the motor and an elevating member ascending the inclined block when the length adjustment member is lengthened, and descending from the inclined block when the length adjustment member is shortened.

In some embodiments, when the elevating member ascends the inclined block, the elevating member descends a first point of the inclined block so that a second point of the probe card corresponding to the first point descends, and when the elevating member descends the inclined block, the elevating member ascends a third point of the inclined block so that a fourth point of the probe card corresponding to the third point ascends.

In some embodiments, the plurality of sensors may measure a distance between the plurality of points of the probe card.

In some embodiments, the controller may determine that the probe card is in an equilibrium state when the deviation or difference of the plurality of displacement values is included in a predetermined range.

According to an aspect of the present disclosure, there is provided a method of aligning a probe card, which is performed by at least one processor. The method may comprise determining whether the probe card is in an equilibrium state, based on a plurality of displacement values measured from a plurality of sensors, determining a target balance adjustment assembly to be adjusted in length among a plurality of balance adjustment assemblies based on a deviation or difference of the plurality of displacement values when it is determined that the probe card is out of an equilibrium state and adjusting the length of the determined target balance adjustment assembly so that the probe card is in an equilibrium state.

In some embodiments, the method further may comprise, before determining whether the probe card is in an equilibrium state, docking the probe card in a base unit coupled with a test head, controlling a plurality of motors included in the plurality of balance adjustment assemblies based on a predetermined value and setting the displacement value of each of the plurality of sensors to an initial value.

In some embodiments, the method further may comprise, after controlling the plurality of motors based on a predetermined value, locking the probe card in the base unit by activating one or more probe card lock modules, wherein the setting the displacement value of each of the plurality of sensors to an initial value is performed after controlling one or more probe card lock modules to be locked.

In some embodiments, the determining the target balance adjustment assembly may include determining a shortened length or an extension length of the determined target balance adjustment assembly based on the deviation or difference of the plurality of displacement values, and the adjusting the length of the determined target balance adjustment assembly includes adjusting the length of the determined target balance adjustment assembly based on the determined shortened length or the determined extension length.

In some embodiments, the determining the target balance adjustment assembly may include determining a rotation direction and the number of rotations of a motor based on the deviation or difference of the plurality of displacement values, and the adjusting the length of the determined target balance adjustment assembly includes adjusting the length of the target balance adjustment assembly by controlling the motor included in the determined target balance adjustment assembly based on the determined rotation direction and the number of rotations.

In some embodiments, the determining whether the probe card is in an equilibrium state may include determining that the probe card is in an equilibrium state when the deviation or difference of the plurality of displacement values is included in a predetermined range.

In some embodiments, the method further may comprise, before determining whether the probe card is in an equilibrium state, generating a contact force on one surface of the probe card and acquiring the plurality of displacement values by using the plurality of sensors.

In some embodiments, the generating a contact force on one surface of the probe card may include contacting one surface of the probe card with a wafer.

According to an aspect of the present disclosure, there is provided a control device. The control device may comprise one or more processors; and a memory storing a computer program executed by the one or more processors, wherein the computer program may include instructions for performing, an operation of determining whether a probe card is in an equilibrium state, based on a plurality of displacement values measured from a plurality of sensors, an operation of determining a target balance adjustment assembly to be adjusted in length among a plurality of balance adjustment assemblies based on a deviation or difference of the plurality of displacement values when it is determined that the probe card is out of an equilibrium state and an operation of adjusting the length of the determined target balance adjustment assembly so that the probe card is in an equilibrium state.

In some embodiments, the operation of determining a target balance adjustment assembly may include an operation of determining a shortened length or an extension length of the determined target balance adjustment assembly based on the deviation or difference of the plurality of displacement values, and the operation of adjusting the length of the determined target balance adjustment assembly includes an operation of adjusting the length of the determined target balance adjustment assembly based on the determined shortened length or the determined extension length.

In some embodiments, the operation of determining the target balance adjustment assembly may include an operation of determining a rotation direction and the number of rotations of a motor based on the deviation or difference of the plurality of displacement values, and the operation of adjusting the length of the determined target balance adjustment assembly includes an operation of adjusting the length of the target balance adjustment assembly by controlling the motor included in the determined target balance adjustment assembly based on the determined rotation direction and the number of rotations.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a view illustrating a test system;

FIG. 2 is a view illustrating a state that a probe card is in contact with a wafer;

FIG. 3 is a cross-sectional view illustrating an apparatus for locking a probe card according to one embodiment of the present disclosure;

FIG. 4 is an enlarged cross-sectional view illustrating an alignment module according to one embodiment of the present disclosure;

FIG. 5 is a plan view illustrating an alignment module according to one embodiment of the present disclosure;

FIG. 6 is a view illustrating a position where a sensor is installed, according to one embodiment of the present disclosure;

FIG. 7 is a flow chart illustrating a method of aligning a probe card according to one embodiment of the present disclosure; and

FIG. 8 is a hardware schematic view illustrating a control device according to some embodiments of the present disclosure.

### DETAILED DESCRIPTION OF THE DISCLOSURE

Hereinafter, preferred embodiments of the present disclosure will be described with reference to the attached drawings. Advantages and features of the present disclosure and methods of accomplishing the same may be understood more readily by reference to the following detailed description of preferred embodiments and the accompanying drawings. The present disclosure may, however, be embodied in many different forms and should not be construed as being limited to the embodiments set forth herein. Rather, these embodiments are provided so that this disclosure will be thorough and complete and will fully convey the concept of the disclosure to those skilled in the art, and the present disclosure will only be defined by the appended claims.

In adding reference numerals to the components of each drawing, it should be noted that the same reference numerals are assigned to the same components as much as possible even though they are shown in different drawings. In addition, in describing the present disclosure, when it is determined that the detailed description of the related well-known configuration or function may obscure the gist of the present disclosure, the detailed description thereof will be omitted.

Unless otherwise defined, all terms used in the present specification (including technical and scientific terms) may be used in a sense that can be commonly understood by those skilled in the art. In addition, the terms defined in the commonly used dictionaries are not ideally or excessively interpreted unless they are specifically defined clearly. The terminology used herein is for the purpose of describing particular embodiments only and is not intended to be limiting of the disclosure. In this specification, the singular also includes the plural unless specifically stated otherwise in the phrase.

In addition, in describing the component of this disclosure, terms, such as first, second, A, B, (a), (b), can be used. These terms are only for distinguishing the components from other components, and the nature or order of the components is not limited by the terms. If a component is described as being “connected,” “coupled” or “contacted” to another component, that component may be directly connected to or contacted with that other component, but it should be understood that another component also may be “connected,” “coupled” or “contacted” between each component.

The terms “comprise”, “include”, “have”, etc. when used in this specification, specify the presence of stated features, integers, steps, operations, elements, components, and/or combinations of them but do not preclude the presence or addition of one or more other features, integers, steps, operations, elements, components, and/or combinations thereof.

In the embodiments of the present disclosure, “alignment” of a probe card may mean that the probe card is in an “equilibrium” state. That is, aligning the probe card may mean that the probe card is in an equilibrium state.

Hereinafter, some embodiments of the present disclosure will be described in detail in accordance with the accompanying drawings.

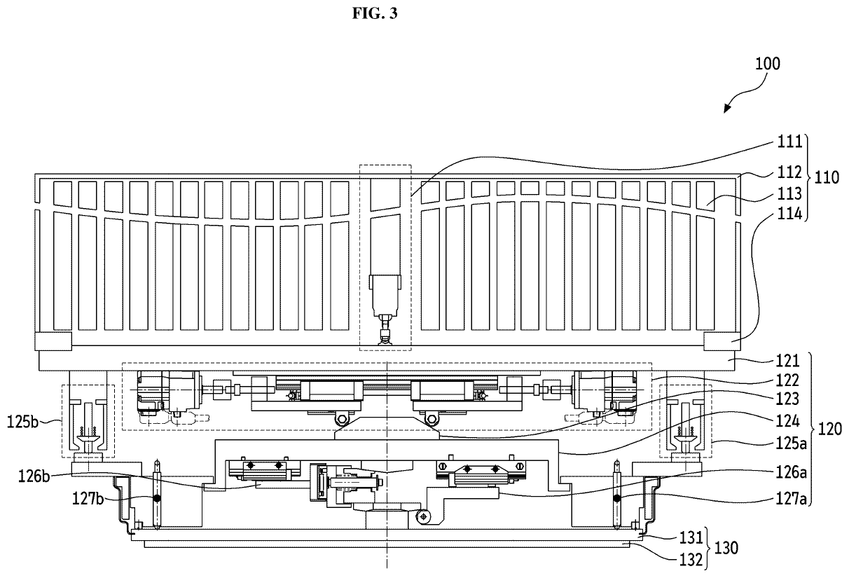

FIG. 3 is a cross-sectional view illustrating an apparatus 100 for locking a probe card according to one embodiment of the present disclosure.

As shown in FIG. 3, the apparatus 100 for locking a probe card may include a test head 110 and a base unit 120.

The test head 110 may include a base unit support member 111, a frame 112, a plurality of test boards 113, and a lock module 114. Furthermore, the test head 110 may be electrically connected to a main body of the apparatus, and may transmit a response signal reacted by the device under test (DUT) included in the wafer (not shown) to the main body of the apparatus. In this case, the main body of the apparatus may be a tester that transmits a test signal to the device under test, and determines good quality of the device under test based on the response signal responded to the test signal.

The frame 112 may be formed on one or more surfaces of the test head 110 to perform a function of accommodating and protecting the test board 113.

The test board 113 has a rectangular shape, and a plurality of test boards may be mounted on the test head 110. The test board 113 may generate an electrical signal for testing the device under test.

The lock module 114 may couple and lock the test head 110 to the base unit 120.

In the embodiment of the present disclosure, the test head 110 may include a base unit support member 111 disposed in a center area of the test head 110 to perform a center frame function.

The base unit support member 111 may compensate for sagging of the base unit 120. In other words, the lock module 114 may be positioned in an area of both sides, and the test head 110 and the base unit 120 may be coupled to each other by a coupling force by the lock module 114. However, due to the structure in which the lock module 114 is disposed in the area of both sides, a center area of the base unit 120 may become weak, resulting in sagging, which may deteriorate a test quality in testing the device under test included in the wafer.

To compensate for vulnerability of the center area of the base unit 120, the base unit support member 111 may be disposed in the center area of the test head 110 and tightly coupled to an upper end of the base frame 121 of the base unit 120 to support the center area of the base unit 120.

The base unit 120 may include a base frame 121, an alignment module 122, an inclined block 123, a center clamp 124, a plurality of floating units 125a and 125b, a plurality of card lock modules 126a and 126b, and a plurality of sensors 127a to 127d.

The probe card 130 may include a reinforcing member 131 and a printed circuit board (PCB) 132. Although not shown in the drawing, the probe card 130 may include a plurality of pins formed on a lower surface of the PCB 132, being in contact with the device under test on the wafer. Furthermore, the probe card 130 may include a coupling member (not shown) that may be coupled to the plurality of card lock modules 126a and 126b.

The PCB 132 forms a circuit for testing the device under test, and the reinforcing member 131 may be installed on an upper surface of the PCB 132 to protect the PCB 132 from external impact.

According to one embodiment, the alignment module 122 may be coupled to a lower portion of the base frame 121. According to one embodiment, at least one of balance adjustment assemblies 210a to 210d included in the alignment module 122 may be locked after moving an inclined surface of the inclined block 123 by a predetermined distance so that the probe card 130 is aligned. A moving distance and a moving direction for each of the balance adjustment assemblies 210a to 210d may be determined by a controller (not shown). In this case, the controller is configured to include a processor, and may be included in the apparatus 100 for locking a probe card.

The plurality of floating units 125a and 125b may be disposed in the base unit 120. The floating units 125a and 125b may have a spring installed therein to be floated in XYZ direction.

The center clamp 124 may be disposed between the alignment module 122 and the card lock modules 126a and 126b.

The inclined block 123 having a predetermined size and slope may be formed in a center area of the center clamp 124. The slope may be formed in a predetermined direction and angle. According to one embodiment, slopes equivalent to the number of balance adjustment assemblies 210a to 210d may be formed in the inclined block 123 in a plurality of directions. For example, when there are four balance adjustment assemblies 210a to 210d, the inclined block 123 may have slopes in four directions.

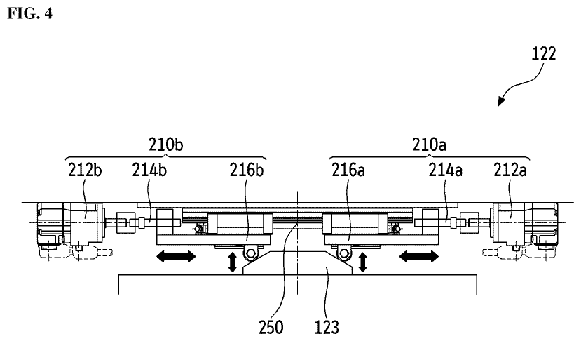

FIG. 4 is an enlarged cross-sectional view illustrating an alignment module 122 according to one embodiment of the present disclosure.

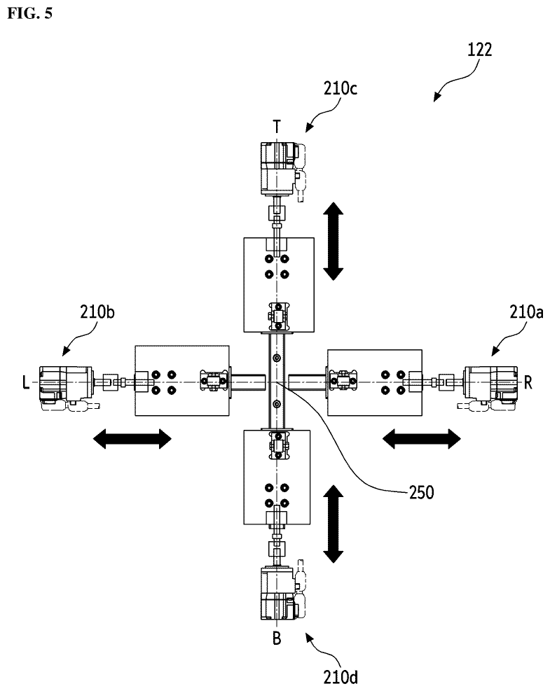

FIG. 5 is a plan view illustrating an alignment module 122 according to one embodiment of the present disclosure.

Referring to FIGS. 4 and 5, the alignment module 122 may include a plurality of balance adjustment assemblies 210a to 210d. As illustrated in FIG. 5, four balance adjustment assemblies 210a to 210d may be included in the alignment module 122. Lengths of the balance adjustment assemblies 210a to 210d may be extended in different directions. For example, the length of the first balance adjustment assembly 210a may be extended in a direction of an azimuth angle of 90°, the length of the second balance adjustment assembly 210b may be extended in a direction of an azimuth angle of 180°, the length of the third balance adjustment assembly 210c may be extended in a direction of an azimuth angle of 270°, and the fourth balance adjustment assembly 210d may be extended in a direction of an azimuth angle of 360°.

As illustrated in FIG. 4, the plurality of balance adjustment assemblies 210a and 210b may include motors 212a and 212b, length adjustment members 214a and 214b, and elevating members 216a and 216b. In this case, the motors 212a and 212b may be servo motors. Also, when the motors 212a and 212b are rotated in a clockwise direction, lengths of the length adjustment members 214a and 214b may be configured to be shortened, when the motors 212a and 212b are rotated in a counterclockwise direction, the lengths adjustment members 214a and 214b may be configured to be lengthened. In some embodiments, when the motors 212a and 212b are rotated in a counterclockwise direction, lengths of the length adjustment members 214a and 214b may be configured to be shortened, when the motors 212a and 212b are rotated in a clockwise direction, the lengths adjustment members 214a and 214b may be configured to be lengthened. The length adjustment members 214a and 214b may include a ball screw for converting a linear motion into a rotational motion of the motors 212a and 212b, and may include a bar of a variable length.

Each of the plurality of balance adjustment assemblies 210a and 210b may be adjusted in length so that one end thereof is close to a center point 250, or may be adjusted in length so that one end thereof becomes far away from the center point 250. That is, each of the plurality of balance adjustment assemblies 210a to 210d may have one end extended in a direction of the inclined block 123 and the center point 250, and may be shortened in a direction opposite to the inclined block 123 and the center point 250.

Each of the plurality of elevating members 216a and 216b may include a rotating member such as a roller on a lower portion so that each elevating member may ascend or descend the elevating block 123.

Although not shown in FIG. 4, the third balance adjustment assembly 210c and the fourth balance adjustment assembly 210d may also include a motor, a length adjustment member, and an elevating member.

According to one embodiment, each of the plurality of sensors 127a to 127dmay measure a displacement value of the probe card 130. In this case, the displacement value may indicate a value changed from a reference value.

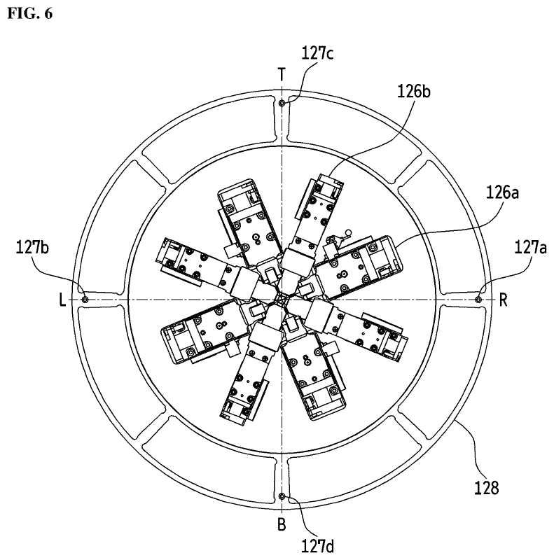

FIG. 6 is a view illustrating a position where a sensor is installed, according to one embodiment of the present disclosure.

Referring to FIG. 6, the plurality of sensors 127a to 127d may be disposed at predetermined positions.

The plurality of sensors 127a to 127d may be disposed in the base unit 120 to measure displacement values for a plurality of points of the probe card 130. In FIG. 6, the plurality of sensors 127a to 127d are illustrated as being disposed to be spaced apart from each other at constant intervals in a circular member 128. In FIG. 6, four sensors 127a to 127d are illustrated as being disposed. Each of the sensors 127a to 127d may sense a distance value to a specific point or part of the probe card 130.

Whether the probe card 130 is in an equilibrium state may be determined based on the displacement values measured from the plurality of sensors 127a to 127d. When a deviation or difference with respect to the plurality of displacement values is included in a predetermined range, the controller may determine that the probe card 130 is in an equilibrium state. For example, when all (or some) of a first deviation based on a first displacement value measured through the first sensor 127a, a second deviation based on a second displacement value measured through the second sensor 127b, a third deviation based on a third displacement value measured through the third sensor 127c and a fourth deviation based on a fourth displacement value measured through the fourth sensor 127d are included in a predetermined range, it may be determined that the probe card 130 is in an equilibrium state. On the other hand, when the deviation with respect to the plurality of displacement values is out of a predetermined range, the controller may determine that the probe card 130 is out of the equilibrium state. For example, when all (or some) of the first deviation based on the first displacement value measured through the first sensor 127a, the second deviation based on the second displacement value measured through the second sensor 127b, the third deviation based on the third displacement value measured through the third sensor 127c and the fourth deviation based on the fourth displacement value measured through the fourth sensor 127d are included in a predetermined range, it may be determined that the probe card 130 is not in an equilibrium state.

In some embodiments, the controller may calculate a difference between the plurality of displacement values, and may determine that the probe card 130 is in an equilibrium state when the difference between the calculated displacement values is included in a predetermined range. For example, the controller may calculate a first difference value between the first displacement value measured through the first sensor 127a and the second displacement value measured through the second sensor 127b, a second difference value between the first displacement value measured through the first sensor 127a and the third displacement value measured through the third sensor 127c, and a third difference value between the first displacement value measured through the first sensor 127a and the fourth displacement value measured through the fourth sensor 127d, respectively, and may determine that the probe card 130 is in an equilibrium state when all (or some) of the calculated first, second and third difference values are included in a predetermined range.

In some embodiments, the controller may calculate a difference between displacement values measured through a pair of sensors facing each other, and may determine that the probe card 130 is in an equilibrium state, based on the calculated difference. For example, the controller may calculate a first difference value between the first displacement value measured through the first sensor 127a and the second displacement value measured through the second sensor 127b and calculate a fourth difference value between the third displacement value measured through the third sensor 127c and the fourth displacement value measured through the fourth sensor 127d, and then may determine that the probe card 130 is in an equilibrium state when both the calculated first difference value and the calculated fourth difference value are included in a predetermined range.

When it is determined that the state of the probe card 130 determined based on the displacement values measured from the plurality of sensors 127a to 127d is out of an equilibrium state, the length of one or more of the plurality of balance adjustment assemblies 210a to 210d may be increased or shortened based on the plurality of displacement values so that the probe card 130 becomes a predetermined state.

As illustrated in FIG. 6, the sensors 127a to 127d may be disposed in four directions. For example, the four sensors 127a to 127d may be disposed at intervals of 90°. According to some embodiments, a specific sensor may be disposed at a position where a distance between first points of the probe card 130 is measured. For example, the first sensor 127a may be disposed at a first point of the base unit 120, which is capable of sensing a displacement value with respect to the first point of the probe card 130, and the second sensor 127b may be disposed at a second point of the base unit 120, which is capable of sensing a displacement value with respect to a second point of the probe card 130. In addition, the third sensor 127c may be disposed at a third point of the base unit 120, which is capable of sensing a displacement value with respect to a third point of the probe card 130, and the fourth sensor 127d may be disposed at a fourth point of the base unit 120, which is capable of sensing a displacement value with respect to a fourth point of the probe card 130.

The controller included in the apparatus 100 for locking a probe card may control the lengths of one or more balance adjustment assemblies 210a to 210d based on the plurality of displacement values measured from the plurality of sensors 127a to 127d. That is, at least one balance adjustment assembly 210a, 210b, 210c or 210d may be controlled under the control of the controller, and thus may be extended in a direction of the inclined block 123, or may be shortened in an opposite direction of the inclined block 123. According to one embodiment, the controller may individually adjust the lengths of the balance adjustment assemblies 210a to 210d based on the plurality of displacement values.

Referring to FIG. 4, when the balance adjustment assemblies 210a to 210d are lengthened in the direction of the inclined block 123 so that the elevating members 216a and 216b ascend the inclined block 123, a force is applied in a downward direction so that the probe card 130 may descend by a predetermined height. That is, when the elevating members 216aand 216b ascend the inclined block 123, the elevating members 216a and 216b descend a first point of the inclined block so that the second point of the probe card 130 corresponding to the first point of the inclined block may descend.

On the contrary, when the balance adjustment assemblies 210a to 210d are shortened in the opposite direction of the inclined block 123 so that the elevating members 216a and 216b descend the inclined block 123, a force for pressing the probe card 130 may be weakened, and thus the probe card 130 may ascend by a predetermined height. That is, when the elevating members 216a and 216b descend the inclined block 123, the elevating members 216a and 216b may ascend a third point of the inclined block 123, so that the fourth point of the probe card 130 corresponding to the third point of the inclined block 123 may ascend.

Through this principle, the plurality of balance adjustment assemblies 210a to 210d may be controlled such that the inclined probe card becomes in an equilibrium state. That is, in accordance with the adjustment of the lengths of the plurality of balance adjustment assemblies 210a to 210d, a specific point among the plurality of points included in the probe card 130 may ascend or descend so that the probe card 130 may be in an equilibrium state. For example, when the fourth point of the probe card 130 ascends more than the other points so that the probe card 130 is in an inclined state (i.e., out of the equilibrium state), a specific balance adjustment assembly may be lengthened such that a third point of the inclined block 123 corresponding to the fourth point of the probe card may descend, thereby descending the fourth point of the probe card.

As described above, the controller included in the apparatus 100 for locking a probe card may adjust the length of each of the plurality of balance adjustment assemblies 210a to 210d. According to one embodiment, the controller may adjust the length of each of the plurality of balance adjustment assemblies 210a to 210d by controlling the motor included in the plurality of balance adjustment assemblies 210a to 210d.

The controller may determine whether the probe card 130 is in an equilibrium state based on the plurality of displacement values measured from the plurality of sensors 127a to 127d. According to one embodiment, when the deviation (or difference) of the plurality of displacement values is included in a predetermined range, the controller may determine that the probe card 130 is in an equilibrium state.

When it is determined that the probe card 130 is out of an equilibrium state, the controller may control the probe card to be in an equilibrium state by adjusting the length of at least one of the plurality of balance adjustment assemblies 210a to 210d.

In addition, when the probe card is out of the equilibrium state, the controller may determine a target balance adjustment assembly to be adjusted in length among the plurality of balance adjustment assemblies 210a to 210d and adjust the length of the determined target balance adjustment assembly, based on the deviation (or difference) of the plurality of displacement values. For example, when the first displacement value measured from the first sensor 127a is calculated to be smaller than the second displacement value measured from the second sensor 127b by a threshold value or more, the probe card 130 may be inclined in a state that the third point of the probe card 130, which is related to the first displacement value, is high and the fourth point of the probe card 130, which is related to the second displacement value, is low. In this case, the controller may adjust the length of the first balance adjustment assembly 210a, which is related to the first displacement value, to be extended so that the third point becomes low. Additionally or alternatively, the controller may control the length of the second balance adjustment assembly 210b, which is related to the second displacement value, to be shortened so that the fourth point becomes high.

According to one embodiment, the controller may determine a shortened length or an extension length of the target balance adjustment assembly based on the deviation (or difference) of the plurality of displacement values, and may adjust the length of the determined target balance adjustment assembly based on the determined shortened length or extension length. According to one embodiment, the controller may determine a shortened length or an extension length, which corresponds to the displacement value and the deviation (or difference), with reference to a table in which the shortened length or extension length for each deviation (for each difference) of the displacement value is mapped.

According to one embodiment, the controller may determine a rotation direction and the number of rotations of the motor based on the determined shortened length or extension length, and may control the motor included in the determined target balance adjustment assembly based on the determined rotation direction and the number of rotations to adjust the length of the target balance adjustment assembly. According to one embodiment, the controller may determine the rotation direction and the number of rotations of the motor, which correspond to the shortened length or the extension length, with reference to a second table in which the rotation direction and the number of rotations of the motor are recorded for each shortened length and extension length.

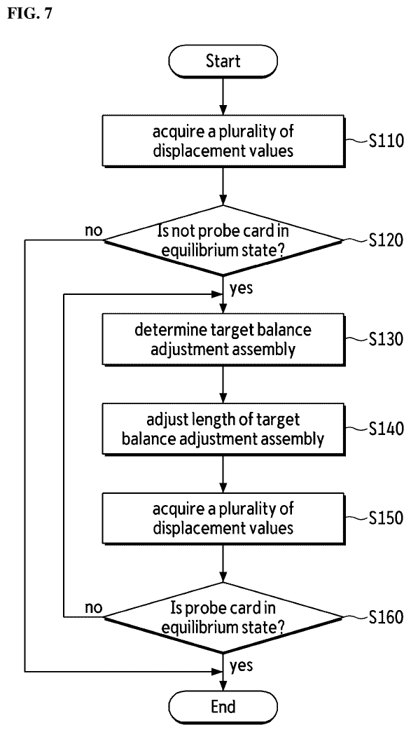

A method of aligning a probe card according to the embodiment of the present disclosure will be described with reference to FIG. 7.

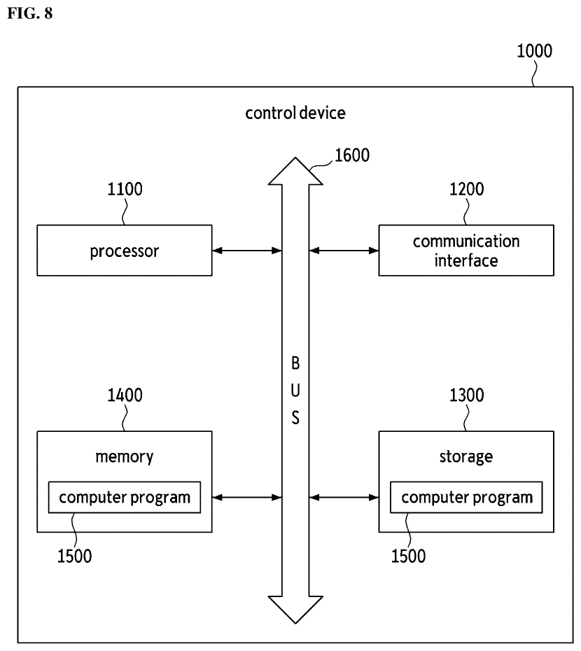

The method shown in FIG. 7 is only one embodiment for achieving the object of the present disclosure, and some steps may be added or deleted as necessary. In addition, the method shown in FIG. 7 may be performed by at least one processor included in a control device of FIG. 8, or may be performed by the controller. For convenience of description, it will be described on the assumption that each method illustrated in FIG. 7 is performed by the processor included in the control device of FIG. 8.

FIG. 7 is a flow chart illustrating a method of aligning a probe card according to one embodiment of the present disclosure.

Referring to FIG. 7, when the probe card 130 is docked, the processor may power on a plurality of motors 212a and 212b included in a plurality of balance adjustment assemblies 210a to 210d, and then may power off brakes on the motors 212a and 212b, whereby the motors 212a and 212b may move. In this case, docking may mean that the probe card 130 is connected to the base unit 120.

Afterwards, the controller may control each of the plurality of motors 212a and 212b based on a predetermined initial value (e.g., home value) so that the plurality of balance adjustment assemblies 210a to 210d have a predetermined length. Then, the controller may activate the first card lock modules 126a and the second card lock modules 126b to lock the probe card 130 in the base unit 120 through the first card lock modules 126a and the second card lock modules 126b.

Subsequently, the controller may set the displacement value for each of the plurality of sensors 127a to 127d to an initial value. For example, the initial value may be ‘0 (zero)’. Then, the controller may power on the brakes on each of the motors 212a and 212b, and may power off each of the plurality of motors 212a and 212b, thereby controlling the motors 212a and 212b not to rotate.

In this way, after the initial setting related to docking is completed, the controller may artificially generate a contact force on one surface of the probe card 130. According to one embodiment, the controller may artificially generate a predetermined contact force on the probe card 130 by making one surface of the probe card 130 contact the upper surface of the wafer. For example, in the same manner as in the test process for the device under test, a plurality of pins on the lower surface of the probe card 130 may be brought into contact with a plurality of devices under test on the upper surface of the wafer. In this case, the generation time of the contact force may be maintained for a predetermined time. That is, the contact between the probe card 130 and the wafer may be maintained for a predetermined time.

Afterwards, the processor may acquire a plurality of displacement values for a plurality of points of the probe card 130 by using the plurality of sensors 127a to 127d (S110).

Next, the processor may determine whether the probe card 130 is in an equilibrium state based on the plurality of displacement values (S120). When it is determined that the probe card 130 is out of the equilibrium state, the processor may determine the target balance adjustment assembly to be adjusted in length among the plurality of balance adjustment assemblies based on the deviation or difference of the plurality of displacement values (S130). According to some embodiments, the processor may determine the rotation direction and the number of rotations of the motor based on the deviation or difference of the plurality of displacement values.

Subsequently, the processor may adjust the length of the determined target balance adjustment assembly so that the probe card is in an equilibrium state (S140). The processor may adjust the length of the determined target balance adjustment assembly based on the determined shortened length or extension length. According to some embodiments, the processor may control the motor included in the determined target balance adjustment assembly based on the determined rotation direction and the determined number of rotations, thereby adjusting the length of the target balance adjustment assembly.

Then, the processor may re-acquire the plurality of displacement values by using the plurality of sensors 127a to 127d (S150).

Next, the processor may determine whether the probe card 130 is in an equilibrium state based on the acquired displacement values (S160). When it is determined that the probe card 130 is still out of the equilibrium state, the processor may proceed to step S130 again to adjust the length of at least one balance adjustment assembly.

Meanwhile, in step S120 or step S160, when it is determined that the probe card 130 is in an equilibrium state, the processor may proceed with a process of contacting the probe card 130 with the device under test on the wafer. Then, the device under test may be tested.

FIG. 8 is a hardware configuration view of an exemplary control device 1000 according to some embodiments of the present disclosure. The control device 1000 may include at least one processor 1100, a bus 1600, a communication interface 1200, a memory 1400, which loads a computer program 1500 to be executed by the processor 1100, and a storage 1300, which stores the computer program 1500.

The processor 1100 may control the overall operations of the components of the control device 1000. The processor 1100 may perform operations related to at least one application or program to execute operations/methods according to various embodiments of the present disclosure. The memory 1400 may store various data, commands, and/or information. The memory 1400 may load the computer program 1500 from the storage 1300 to execute the operations/methods according to various embodiments of the present disclosure. The storage 1300 may non-transitorily store at least one computer program 1500.

The computer program 1500 may include one or more instructions that enable the processor 1100 to perform the operations/methods according to various embodiments of the present disclosure when loaded into the memory 1400. In other words, by executing the loaded instructions, the processor 1100 may perform the operations/methods according to various embodiments of the present disclosure.

According to one embodiment, the computer program 1500 may include instructions for performing an operation of determining whether a probe card is in an equilibrium state, based on a plurality of displacement values measured from a plurality of sensors, an operation of determining a target balance adjustment assembly to be adjusted in length among a plurality of balance adjustment assemblies based on a deviation or difference of the plurality of displacement values when it is determined that the probe card is out of an equilibrium state and an operation of adjusting the length of the determined target balance adjustment assembly so that the probe card is in an equilibrium state.

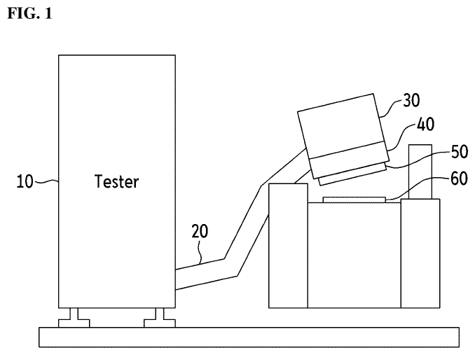

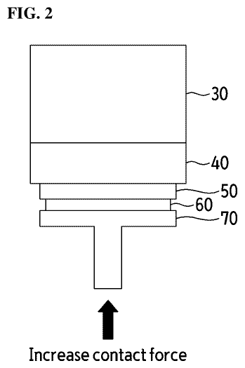

So far, a variety of embodiments of the present disclosure and the effects according to embodiments thereof have been mentioned with reference to FIGS. 1 to 8. The effects according to the technical idea of the present disclosure are not limited to the forementioned effects, and other unmentioned effects may be clearly understood by those skilled in the art from the description of the specification.

The methods according to the embodiments of the present disclosure described above may be performed by executing a computer program implemented using a computer- readable code. The computer program may be transmitted from a first computing device to a second computing device via a network such as the Internet and installed on the second computing device, and may be used by the second computing device. Furthermore, although the operations are illustrated in a specific order in the drawings, it should not be understood that the operations should be executed in the specific order as illustrated or in a sequential order or that all illustrated operations should be executed to acquire a desired result. In certain situations, multitasking and parallel processing may be advantageous.

Although some embodiments of the present disclosure have been described above with reference to the accompanying drawings, the present disclosure may not be limited to some embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that some embodiments as described above are not restrictive but illustrative in all respects. What is claimed is:

1. An apparatus for locking a probe card, the apparatus comprising:
a test head including one or more test boards;
a probe card;
a base unit disposed between the test head and the probe card and coupled to each of the test head and the probe card, including a plurality of balance adjustment assemblies and a plurality of sensors measuring a plurality of displacement values of a plurality of points of the probe card; and
a controller determining whether the probe card is in an equilibrium state, based on the plurality of displacement values measured from the plurality of sensors, and controlling the probe card to be in an equilibrium state by adjusting a length of at least one of the plurality of balance adjustment assemblies when it is determined that the probe card is out of the equilibrium state.

2. The apparatus of claim 1, wherein the controller determines a target balance adjustment assembly to be adjusted in length among the plurality of balance adjustment assemblies, based on a deviation or difference of the plurality of displacement values when the probe card is out of the equilibrium state, and adjusts a length of the determined target balance adjustment assembly.

3. The apparatus of claim 2, wherein the controller determines a shortened length or an extension length of the determined target balance adjustment assembly, based on the deviation or difference of the plurality of displacement values, and controls the length of the determined target balance assembly based on the determined shortened length or the determined extension length.

4. The apparatus of claim 2, wherein the controller determines a rotation direction and the number of rotations of a motor based on the deviation or difference of the plurality of displacement values, and controls the motor included in the determined target balance adjustment assembly based on the determined rotation direction and the number of rotations to adjust the length of the determined target balance adjustment assembly.

5. The apparatus of claim 1, wherein the base unit further includes:
a center clamp; and
an inclined block formed above the center clamp, enabling one end of the plurality of balance adjustment assemblies to ascend or descend.

6. The apparatus of claim 5, wherein each of the plurality of balance adjustment assemblies includes:
a motor;
a length adjustment member coupled to one end of the motor and lengthened in a direction of the inclined block or shortened in an opposite direction of the inclined block in accordance with rotation of the motor; and
an elevating member ascending the inclined block when the length adjustment member is lengthened, and descending from the inclined block when the length adjustment member is shortened.

7. The apparatus of claim 6, wherein, when the elevating member ascends the inclined block, the elevating member descends a first point of the inclined block so that a second point of the probe card corresponding to the first point descends, and
when the elevating member descends the inclined block, the elevating member ascends a third point of the inclined block so that a fourth point of the probe card corresponding to the third point ascends.

8. The apparatus of claim 1, wherein the plurality of sensors measure a distance between the plurality of points of the probe card.

9. The apparatus of claim 1, wherein the controller determines that the probe card is in an equilibrium state when the deviation or difference of the plurality of displacement values is included in a predetermined range.

10. A method of aligning a probe card, which is performed by at least one processor, the method comprising:
determining whether the probe card is in an equilibrium state, based on a plurality of displacement values measured from a plurality of sensors;
determining a target balance adjustment assembly to be adjusted in length among a plurality of balance adjustment assemblies based on a deviation or difference of the plurality of displacement values when it is determined that the probe card is out of an equilibrium state; and
adjusting the length of the determined target balance adjustment assembly so that the probe card is in an equilibrium state.

11. The method of claim 10, further comprising, before determining whether the probe card is in an equilibrium state:
docking the probe card in a base unit coupled with a test head;
controlling a plurality of motors included in the plurality of balance adjustment assemblies based on a predetermined value; and
setting the displacement value of each of the plurality of sensors to an initial value.

12. The method of claim 11, further comprising, after controlling the plurality of motors based on a predetermined value, locking the probe card in the base unit by activating one or more probe card lock modules,
wherein the setting the displacement value of each of the plurality of sensors to an initial value is performed after controlling one or more probe card lock modules to be locked.

13. The method of claim 10, wherein the determining the target balance adjustment assembly includes determining a shortened length or an extension length of the determined target balance adjustment assembly based on the deviation or difference of the plurality of displacement values, and
the adjusting the length of the determined target balance adjustment assembly includes adjusting the length of the determined target balance adjustment assembly based on the determined shortened length or the determined extension length.

14. The method of claim 10, wherein the determining the target balance adjustment assembly includes determining a rotation direction and the number of rotations of a motor based on the deviation or difference of the plurality of displacement values, and
the adjusting the length of the determined target balance adjustment assembly includes adjusting the length of the target balance adjustment assembly by controlling the motor included in the determined target balance adjustment assembly based on the determined rotation direction and the number of rotations.

15. The method of claim 10, wherein the determining whether the probe card is in an equilibrium state includes determining that the probe card is in an equilibrium state when the deviation or difference of the plurality of displacement values is included in a predetermined range.

16. The method of claim 10, further comprising, before determining whether the probe card is in an equilibrium state:
generating a contact force on one surface of the probe card; and
acquiring the plurality of displacement values by using the plurality of sensors.

17. The method of claim 16, wherein the generating a contact force on one surface of the probe card includes contacting one surface of the probe card with a wafer.

18. A control device comprising:
one or more processors; and
a memory storing a computer program executed by the one or more processors,
wherein the computer program includes instructions for performing:
an operation of determining whether a probe card is in an equilibrium state, based on a plurality of displacement values measured from a plurality of sensors;
an operation of determining a target balance adjustment assembly to be adjusted in length among a plurality of balance adjustment assemblies based on a deviation or difference of the plurality of displacement values when it is determined that the probe card is out of an equilibrium state; and
an operation of adjusting the length of the determined target balance adjustment assembly so that the probe card is in an equilibrium state.

19. The control device of claim 18, wherein the operation of determining a target balance adjustment assembly includes an operation of determining a shortened length or an extension length of the determined target balance adjustment assembly based on the deviation or difference of the plurality of displacement values, and
the operation of adjusting the length of the determined target balance adjustment assembly includes an operation of adjusting the length of the determined target balance adjustment assembly based on the determined shortened length or the determined extension length.

20. The control device of claim 18, wherein the operation of determining the target balance adjustment assembly includes an operation of determining a rotation direction and the number of rotations of a motor based on the deviation or difference of the plurality of displacement values, and
the operation of adjusting the length of the determined target balance adjustment assembly includes an operation of adjusting the length of the target balance adjustment assembly by controlling the motor included in the determined target balance adjustment assembly based on the determined rotation direction and the number of rotations.
